(19) United States
(12) Patent Application Publication
(10) Pub. No.: US 2023/0389193 A1
(43) Pub. Date: Nov. 30, 2023

(54) FRAME STRUCTURE, INFORMATION DISPLAY DEVICE, AND METHOD FOR MANUFACTURING FRAME STRUCTURE

(71) Applicant: Akihisa Mikawa, KANAGAWA (JP)

(72) Inventor: Akihisa Mikawa, KANAGAWA (JP)

(73) Assignee: Ricoh Company, Ltd., Tokyo (JP)

(21) Appl. No.: 18/319,153

(22) Filed: May 17, 2023

(30) Foreign Application Priority Data
May 27, 2022 (JP) 2022-086816

(51) Int. Cl. H05K 5/00; H05K 5/06

(52) U.S. Cl. CPC H05K 5/0004; H05K 5/06

(57) ABSTRACT

A frame structure includes a first part along a side of an enclosure shape of the frame structure, including an inner side face and a protruding portion including a side face adjacent to the inner side face, a second part attached to the first part, including a first face facing the inner side face and the side face, and a second face facing an end face of the protruding portion; an ear portion protruding along the protruding portion from the second part, into which the first face and the second face extend; a first watertight portion including adhesive applied along an outer edge of the first face on the inner side face and the side face; and a second watertight portion including adhesive applied along a boundary with the end face on the second face. The first watertight portion and the second watertight portion overlap in the ear portion.

### CROSS-REFERENCE TO RELATED APPLICATIONS

This patent application is based on and claims priority pursuant to 35 U.S.C. § 119(a) to Japanese Patent Application No. 2022-086816, filed on May 27, 2022, in the Japan Patent Office, the entire disclosure of which is hereby incorporated by reference herein.

### BACKGROUND

### Technical Field

The present disclosure relates to a frame structure including a plurality of parts assembled to have an enclosure shape, an information display device, and a method for manufacturing the frame structure.

### Related Art

In recent years, with the widespread use of wearable devices and the like, a large number of waterproof mobile terminals (information display devices) that can be used in all weather are available. Waterproofing techniques proposed for such products include a technique of crushing an elastic member such as an O-ring to provide waterproofing, and a technique of bonding with a double-sided adhesive tape or an adhesive to provide waterproofing.

### SUMMARY

Embodiments of the present disclosure provide a frame structure including a plurality of parts that are assembled to have an enclosure shape. The plurality of parts includes a first part having a longitudinal direction along a side of the enclosure shape of the frame structure, a second part attached to the first part, an ear portion, a first watertight portion, and a second watertight portion. The first part includes an inner side face facing a center of the enclosure shape, and a protruding portion protruding from the inner side face toward the center of the enclosure shape. The protruding portion extends along the side of the enclosure shape and includes a side face adjacent to the inner side face. The second part includes a first face facing both the inner side face of the first part and the side face of the protruding portion, and a second face facing an end face of the protruding portion. The ear portion protrudes along the protruding portion from the second part. The first face and the second face of the second part extend into the ear portion. The first watertight portion includes a pressure sensitive adhesive applied along an outer edge of the first face of the second part on the inner side face and the side face of the protruding portion. The second watertight portion includes the pressure sensitive adhesive applied along a boundary with the end face of the protruding portion on the second face of the second part. The first watertight portion and the second watertight portion overlap each other in the ear portion.

Embodiments of the present disclosure provide an information display device including the frame structure; and a front surface portion attached to one side in a center axis direction of the enclosure shape of the frame structure and having a screen that displays information.

Embodiments of the present disclosure provide a method of manufacturing a frame structure including a plurality of parts assembled to have an enclosure shape. The plurality of parts includes a first part having a longitudinal direction along the enclosure shape of the frame structure, a second part attached to the first part, and an ear portion. The first part includes an inner side face facing a center of the enclosure shape, and a protruding portion protruding from the inner side face toward the center of the enclosure shape and extending along the side of the enclosure shape. The protruding portion includes one side face adjacent to the inner side face. The second part includes a first face facing the inner side face of the first part and the one side face of the protruding portion, and a second face facing an end face of the protruding portion. The ear portion protrudes along the protruding portion from the second part. The method includes attaching the second part to the first part; after the attaching, applying a pressure sensitive adhesive, along an outer edge of the first face of the second part, from a direction of the one side face, to form a first watertight portion extending into the ear portion; and after the attaching, applying the pressure sensitive adhesive, along a boundary with the end face of the protruding portion on the second face of the second part, from a direction of another side face of the protruding portion opposite to the one side face, to form a second watertight portion extending into the ear portion. One of the first watertight portion and the second watertight portion is formed and solidified prior to forming the other of the first watertight portion and the second watertight portion, and wherein the first watertight portion and the second watertight portion are formed to overlap each other in the ear portion.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings.

FIG. 1 is a perspective view of an information display device according to an embodiment;

FIG. 2 is an exploded perspective view of the information display device illustrated in FIG. 1;

FIG. 3 is an exploded perspective view of a frame structure according to the embodiment;

FIG. 4 is an exploded perspective view in an enlarged view of an example interface section relating to a power button;

FIG. 5 is an exploded perspective view of the interface section illustrated in FIG. 4 when viewed from the inner side of the frame structure;

FIG. 6 is a perspective view illustrating a joined state of the interface section illustrated in FIG. 4;

FIG. 7 is an exploded perspective view in an enlarged view of an example interface section relating to an alternating-current (AC) adapter;

FIG. 8 is an exploded perspective view of the interface section illustrated in FIG. 7 when viewed from the inner side of the frame structure;

FIG. 9 is a perspective view illustrating a joined state of the interface section illustrated in FIG. 7;

FIG. 10 is a perspective view of the interface section in the joined state illustrated in FIG. 9 when viewed from the rear surface side;

FIG. 11 is a plan view of an example fastened state of an AC adapter bracket and a straight frame when viewed from the positive Z side;

FIG. 12 is a cross-sectional view taken along line A-A in FIG. 11;

FIG. 13 is an exploded perspective view of an example corner section of the frame structure;

FIG. 14 is an exploded perspective view of the corner section illustrated in FIG. 13 when viewed from the inner side of the frame structure;

FIG. 15 is a perspective view illustrating a joined state of the corner section illustrated in FIG. 14;

FIG. 16 is a perspective view of the corner section in the joined state illustrated in FIG. 15 when viewed from the rear surface side;

FIG. 17 is a plan view of an example fastened state of a corner frame and straight frames when viewed from the positive Z side; and

FIG. 18 is a schematic view illustrating a modification of a corner frame.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a”, “an”, and “the” are intended to include the plural forms as well, unless the context clearly indicates otherwise.

According to an embodiment described below, waterproofness can be improved regardless of the shape or size of a frame to be waterproofed. For example, when a water stop portion has a three-dimensional curved surface and when a frame is divided into a plurality of portions, an effect of waterproofing the frame of a large device such as a 42-inch device is provided.

In the following description, the X-direction, the Y-direction, and the Z-direction are perpendicular to each other. The X-direction and the Y-direction are directions parallel to a screen 5 of an information display device 1 according to the embodiment. The X-direction is a short-side direction of the screen 5. The Y-direction is a longitudinal direction of the screen 5. The Z-direction is a stacking direction of a front face portion 2, a frame structure 3, and a rear face portion 4 of the information display device 1. In the following description, the positive Z side may be referred to as a front side and the negative Z side may be referred to as a rear side for the convenience of description.

Configuration of Information Display Device 1

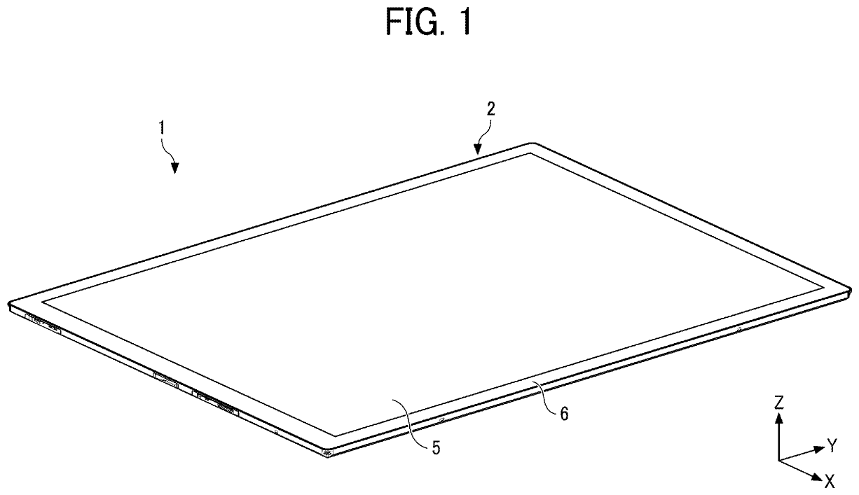

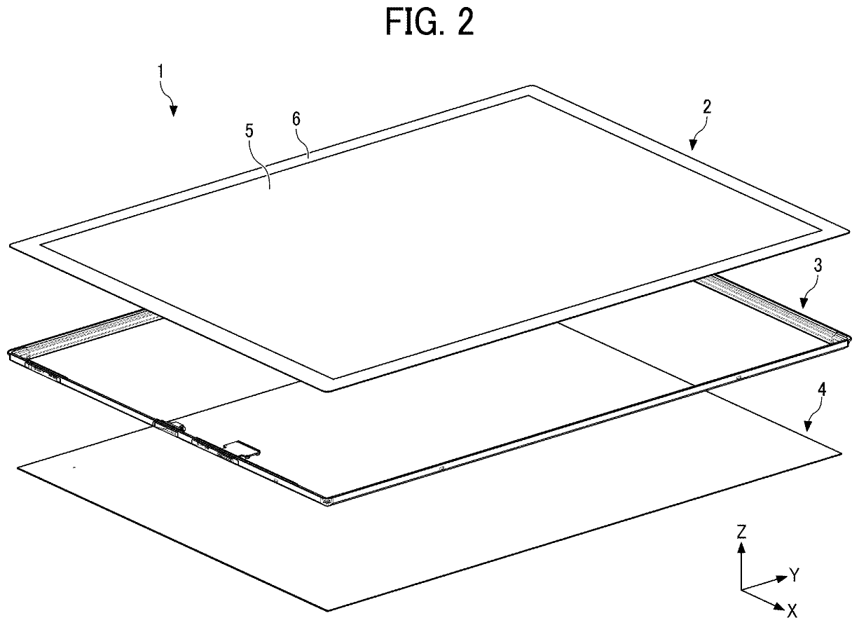

A configuration of the information display device 1 according to the embodiment is described first referring to FIGS. 1 and 2.

FIG. 1 is a perspective view of the information display device 1 according to the embodiment. FIG. 2 is an exploded perspective view of the information display device 1 illustrated in FIG. 1.

The information display device 1 illustrated in FIG. 1 displays information transmitted from a personal computer (PC) or the like on the screen 5 provided on the front side of the information display device 1. With the information display device 1, handwriting input of characters, figures, and the like, can be performed to the screen 5 using a dedicated pen-shaped input device.

The information display device 1 may be, for example, a portable information display device. The rear face portion 4 (described later) has a planar shape. Thus, in one example, the information display device 1 can be placed flat on a desk or the like, that is, placed so that the Z-direction is a substantially vertical direction, and used. A plurality of persons can make a discussion while surrounding the information display device 1 placed flat. In another example, the information display device 1 may be hung from or secured to a wall surface or the like, that is, the information display device 1 may be placed so that the Z-direction is a substantially horizontal direction, and used as an electronic whiteboard or the like.

As illustrated in FIG. 2, the information display device 1 includes the front face portion 2, the frame structure 3, and the rear face portion 4.

The front face portion 2 includes the screen 5 that is a display portion that displays an image, and a bezel 6 that supports the screen 5.

The frame structure 3 holds the front face portion 2 and the rear face portion 4. The frame structure 3 includes circuits and the like for driving the screen 5 of the front face portion 2 and various other functions of the information display device 1, inside the frame structure 3.

The rear face portion 4 is a plate-shaped member that seals the inside of the frame structure 3.

The frame structure 3 is a frame having an enclosure shape, assembled from a plurality of parts. The term “enclosure shape” refers to a continuous shape that surrounds something, and includes a rectangular enclosure shape and a polygonal shape. FIGS. 1 and 2 illustrate a structure having a substantially rectangular shape in view in the Z-direction. The details of the structure of the frame structure 3 will be described later. The frame structure 3 of the present embodiment may have any enclosure shape and may have, for example, a substantially square shape.

The external shapes of the front face portion 2 and the rear face portion 4 in view in the Z-direction are substantially the same as the enclosure shape of the frame structure 3, and are substantially rectangular in view in the Z-direction in FIGS. 1 and 2. Thus, outer edge portions of the front face portion 2 and the rear face portion 4 are brought into contact with the frame structure 3 and are secured.

The size of the information display device 1 is, for example, that the size of the screen 5 is 42 inches, the thickness in the Z-direction is 14.5 mm, and the weight is 5.9 kg. The information display device 1 is thin and lightweight (having the thickness of 14.5 mm and the weight of 5.9 kg) while having the size of 42 inches, and has a dustproof and waterproof function. Devices having a waterproof function are becoming popular in information display devices of 10 inches or less, such as smartphones and tablet PCs. In many cases, these devices are waterproofed by joining a plurality of divided metal frames together through molding. However, in the case of a large device such as a 42-inch device, it is difficult to join a plurality of divided metal frames by molding due to the size of a molding machine. The entire frame can be molded (that is, the metal frames cannot be used), and a frame having a waterproof structure can be formed by molding. However, when the frame is made of resin, there is a disadvantage that it is difficult to increase the rigidity. The resin frame is likely to be twisted as the size increases, and hence it is difficult to employ the resin frame in a large device. Thus, in the case of a large device, it is difficult to form the frame to have the waterproof structure by molding (including molding of the entire frame and joining of metal frames by molding). It is desirable for the frame to have the waterproof structure by a method other than molding.

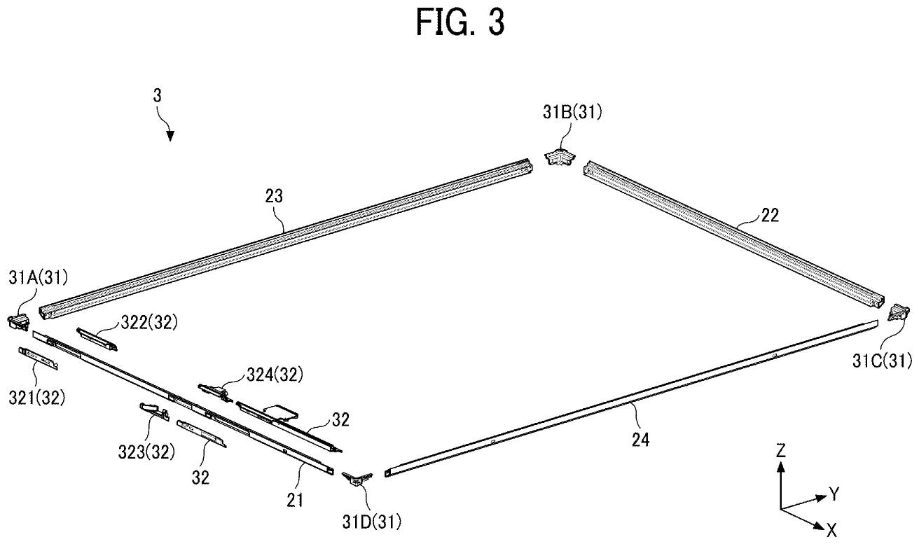

To address the above-described disadvantage, the information display device 1 and the frame structure 3 according to the present embodiment are intended to improve waterproofness regardless of the shape or size. The waterproof structure of the information display device 1 according to the present embodiment will be described below referring to FIG. 3 and subsequent drawings.

Configuration of Frame Structure 3

FIG. 3 is an exploded perspective view of the frame structure 3 according to the embodiment.

As illustrated in FIG. 3, the frame structure 3 of the present embodiment having a substantially rectangular enclosure shape includes four straight frames 21, 22, 23, and 24, and four corner frames 31A, 31B, 31C, and 31D. The straight frames 21 and 22 have the same length and are relatively short. The straight frames 23 and 24 have the same length and are relatively long. The corner frame 31A is coupled between the straight frame 21 and the straight frame 23. The corner frame 31B is coupled between the straight frame 23 and the straight frame 22. The corner frame 31C is coupled between the straight frame 22 and the straight frame 24. The corner frame 31D is coupled between the straight frame 24 and the straight frame 21. Thus, the straight frames 21 and 22 are disposed in parallel to the X-direction and serve as short sides, and the straight frames 23 and 24 are disposed in parallel to the Y-direction and serve as long sides, thereby forming the substantially rectangular frame structure 3.

Since the screen 5 of the information display device 1 according to the present embodiment has a large size of 42 inches, it is desirable for the frame structure 3 to have a relatively high rigidity as a countermeasure against the twist of the frame structure 3. Thus, in the information display device 1, the straight frames 21, 22, 23, and 24 are made of metal. The corner frames 31A, 31B, 31C, and 31D have complicated structures and hence are molded products made of resin.

In the following description, the four corner frames 31A, 31B, 31C, and 31D have the same shape, and hence may be collectively referred to as a “corner frame 31” for the convenience of description.

The frame structure 3 of the present embodiment also includes an interface frame 32 for connection between an AC adapter or an external device and an internal part of the information display device 1 and for installation of various operation buttons. In the example of FIG. 3, a configuration having six interface frames 32 is illustrated. However, the number of interface frames 32 can be appropriately changed. In the example of FIG. 3, all the interface frames 32 are installed in the straight frame 21 among the four straight frames 21, 22, 23, and 24. However, an interface frame 32 may be installed in another straight frame 22, 23, or 24.

The interface frames 32 are paired two by two, and one of each pair is installed from the inner side of the information display device 1 and the other one is installed from the outer side of the information display device 1 while sandwiching the straight frame 21. In the example of FIG. 3, as an example of the interface frames 32, a configuration is illustrated in which a power button cover 321 from the outer side and a power button bracket 322 from the inner side are joined to each other while sandwiching the straight frame 21, and a configuration is illustrated in which an AC adapter cover 323 from the outer side and an AC adapter bracket 324 from the inner side are joined to each other while sandwiching the straight frame 21.

Interface sections, such as an AC adapter section, a power button section, and a Universal Serial Bus (USB) terminal section for external communication, have complicated shapes for waterproofing, and hence are desired to be resin-molded products. Thus, in the present embodiment, any of various interface frames 32 is made of resin.

The frame structure 3 according to the present embodiment has a joint structure including the straight frames 21, 22, 23, and 24 made of metal, and the corner frames 31 and interface frames 32 made of resin, thereby having a configuration that improves waterproofness of the information display device 1.

Basic Joint Structure

A basic waterproof joint structure of a metal frame and a resin frame is described first with reference to the pair of the power button cover 321 and the power button bracket 322 among the interface frames 32.

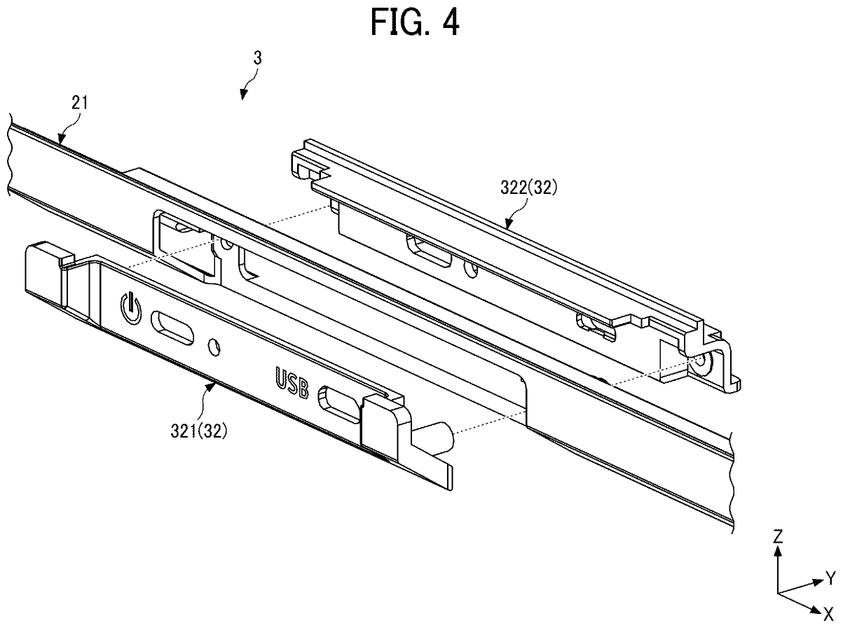

FIG. 4 is an exploded perspective view in an enlarged view of an example interface section relating to a power button. FIG. 4 is a perspective view in the same direction as the direction of FIG. 3, and illustrates, in an enlarged view, a portion of the pair of the power button cover 321 and the power button bracket 322 among the interface frames 32 in FIG. 3.

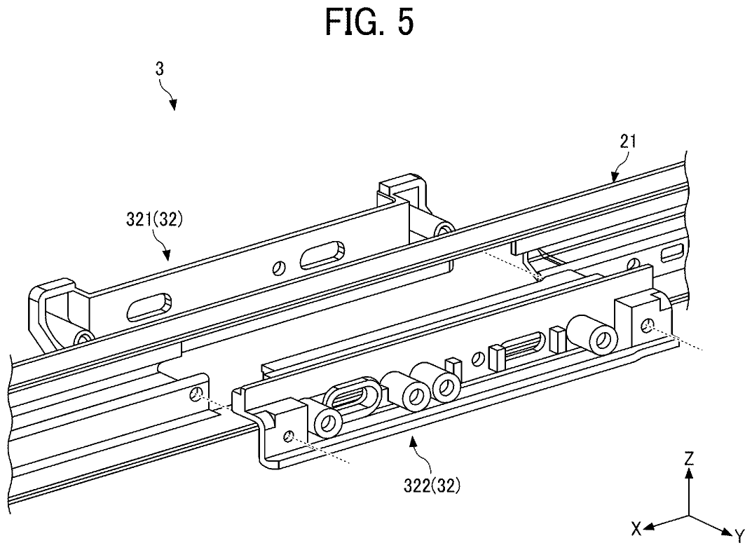

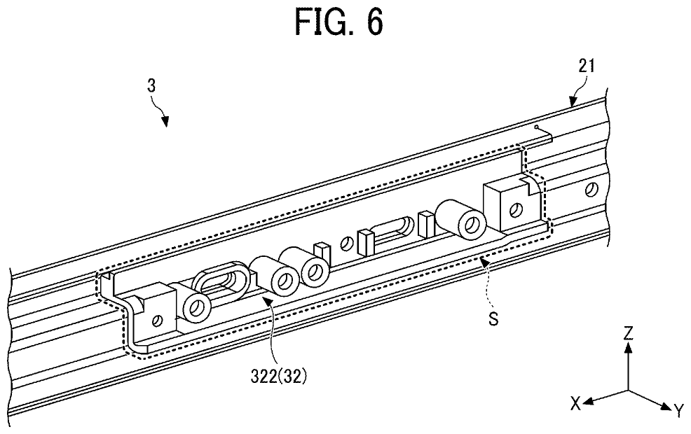

FIG. 4 is a view from the outer side of the frame structure 3. FIG. 5 is an exploded perspective view of the interface section illustrated in FIG. 4 when viewed from the inner side of the frame structure 3. FIG. 5 is a perspective view when the viewpoint is rotated by 90 degrees around the Z-axis with respect to FIG. 4. FIG. 6 is a perspective view illustrating a joined state of the interface section illustrated in FIG. 4. FIG. 6 is a perspective view from the same viewpoint as the viewpoint of FIG. 5, and is a perspective view in a state in which respective parts illustrated in FIG. 5 are assembled.

As illustrated in FIGS. 4 to 6, the power button section includes two parts of the power button cover 321 and the power button bracket 322. The power button cover 321 and the power button bracket 322 are disposed to sandwich the straight frame 21, and both parts are secured to each other via an elastic washer by screw fastening to waterproof a fastening portion.

However, there is a gap between the straight frame 21 made of metal and the power button cover 321 and power button bracket 322 made of resin, and water may enter the inner side through the gap.

Thus, in the present embodiment, as indicated by a dotted line in FIG. 6, a sealant agent is applied to an area along the external shape of the power button bracket 322 on the inner side to form a watertight portion S, thereby filling the gap and attaining waterproofing.

The “sealant” used in the present embodiment is a kind of “pressure sensitive adhesive,” and is a pressure sensitive adhesive that does not contain a volatile component. Also, the “sealant” used in the present embodiment is a kind of typical industrial adhesive, and is “an adhesive that does not contain a volatile component and that does not harden after curing.” Such a definition is made because adhesive including a volatile component may be thinned in the curing process after application, a gap may be formed, and waterproofing is no longer provided. This is also because, when the adhesive hardens after curing, the adhesive may fail to follow expansion and contraction with a change in temperature, and there is a risk of causing interfacial failure after curing.

Further, the “sealant” used in the present embodiment represents a material that fills a joint or a gap of a structure to exhibit functions such as waterproofness and airtightness, and is synonymous with terms such as sealing and caulking. The sealant agent may be in a liquid form or a paste form, and examples of the sealant agent include a sealant agent that functions as it is after application, and a sealant agent that cures into a rubber form.

As illustrated in FIG. 6, the sealant agent is applied to form the watertight portion S between the power button bracket 322 and the straight frame 21, and the sealant agent is not applied between the power button cover 321 and the straight frame 21. To prevent entry of water into the product, it is sufficient to stop water between the power button bracket 322 disposed inside the product and the straight frame 21. The power button cover 321 side is an external appearance surface, and affects the appearance of the product. Thus, in the present embodiment, the sealant agent is applied between the power button bracket 322 located inside the product and the straight frame 21, to form the watertight portion S.

Since the power button bracket 322 is accommodated in one side of the straight frame 21, the sealant agent is applied to the power button section in a manner of one-stroke writing, to form the watertight portion S having an enclosure shape, thereby attaining waterproofing.

The terms “waterproof” and “watertight” also used in the present embodiment do not necessarily mean to simply prevent a liquid such as water from entering the inside of the information display device 1, and may include, for example, to prevent a substance other than a liquid, such as dust, from entering the inside of the information display device 1.

### Joint Structure of Interface Frame 32 According to Embodiment

In the example illustrated in FIGS. 4 to 6, the shape of the power button bracket 322 is designed so that the watertight portion S having the enclosure shape is present entirely on an outer edge portion of the power button bracket 322 on the inner side of the pair of interface frames 32. With this configuration, the gap between the power button bracket 322 and the straight frame 21 can be completely sealed, and hence the waterproofness of the interface frames 32 can be ensured.

In contrast, when the component shapes of the straight frames 21 and the interface frames 32 are more complicated, there may be a structure in which the above-described the watertight portion S having the enclosure shape is not formed. In this case, the gap between the interface frames 32 and the straight frames 21 is not fully sealed, and the waterproofness is not secured. The waterproof joint structure in such a case is described referring to the pair of the AC adapter cover 323 and the AC adapter bracket 324 among the interface frames 32.

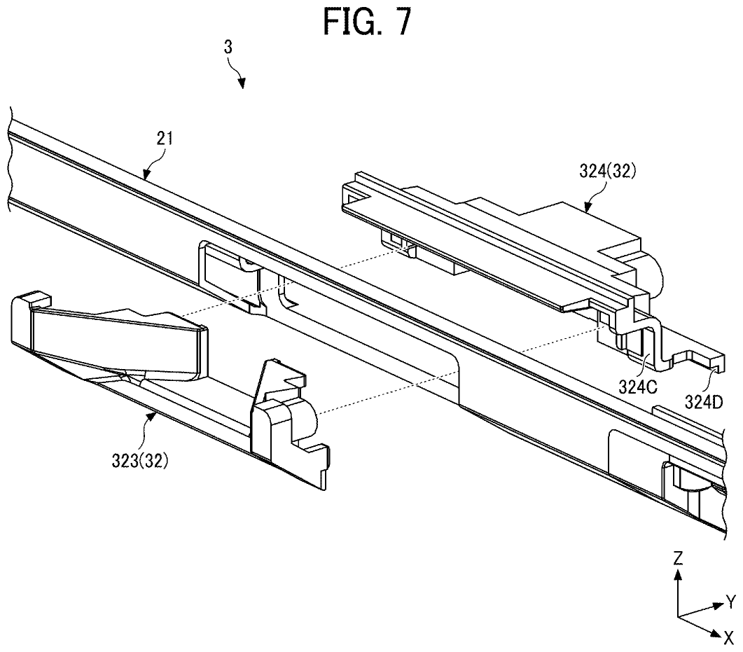

FIG. 7 is an exploded perspective view in an enlarged view of an example interface section relating to the AC adapter in the frame structure 3. FIG. 7 is a perspective view in the same direction as the direction of FIG. 3, and illustrates, in an enlarged view, a portion of the pair of the AC adapter cover 323 and the AC adapter bracket 324 among the interface frames 32 in FIG. 3. FIG. 7 is a view from the outer side of the frame structure 3.

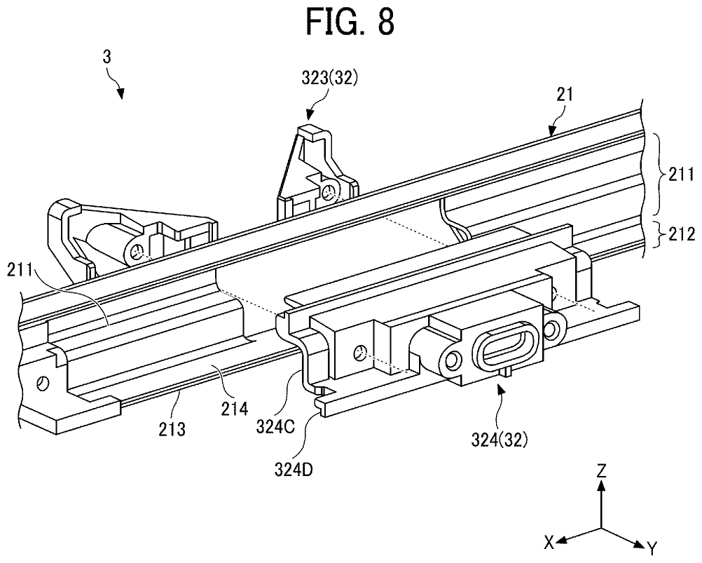

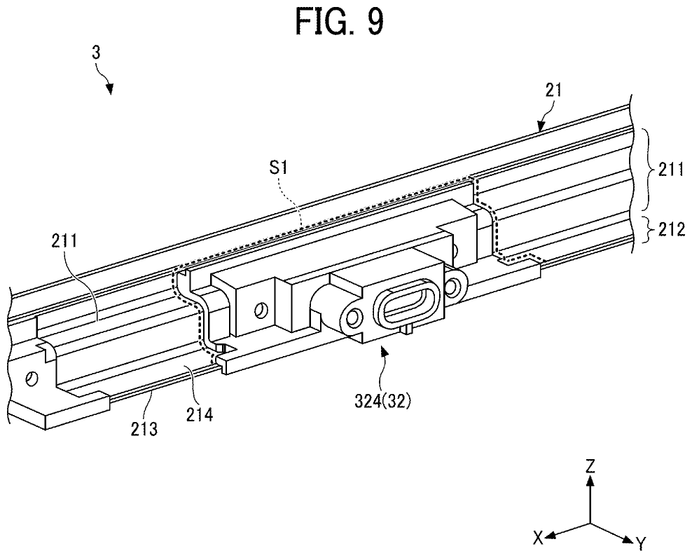

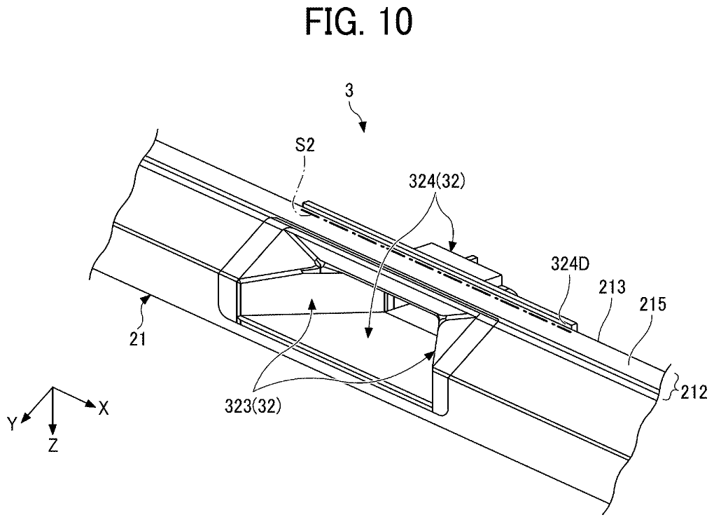

FIG. 8 is an exploded perspective view of the interface section illustrated in FIG. 7 when viewed from the inner side of the frame structure 3. FIG. 8 is a perspective view when the viewpoint is rotated by 90 degrees around the Z-axis with respect to FIG. 7. FIG. 9 is a perspective view illustrating a joined state of the interface section illustrated in FIG. 7. FIG. 9 is a perspective view from the same viewpoint as the viewpoint of FIG. 8, and is a perspective view in a state in which respective parts illustrated in FIG. 8 are assembled. FIG. 10 is a perspective view of the interface section in the joined state illustrated in FIG. 9 when viewed from the rear side. FIG. 10 is a perspective view when the viewpoint is rotated by 180 degrees around the Y-axis and rotated by 90 degrees around the Z-axis with respect to FIG. 9.

As illustrated in FIGS. 7 to 10, the AC adapter section includes two parts, the AC adapter cover 323 and the AC adapter bracket 324. Like the power button section illustrated in FIGS. 4 to 6, the AC adapter cover 323 and the AC adapter bracket 324 (see FIG. 3) are disposed to sandwich the straight frame 21 and secured together via an elastic washer by a screw, to make a fastening portion waterproof.

The idea of applying the sealant agent is similar to that of the power button section. As indicated by a dotted line in FIG. 9, the sealant agent is applied between the AC adapter bracket 324 on the inner side and the straight frame 21 to form a watertight portion (first watertight portion S1) and to provide waterproofing. However, as illustrated in FIGS. 9 and 10, in the AC adapter section, unlike the power button section, the AC adapter bracket 324 is not accommodated in one surface (a series of surfaces facing the inner side) of the straight frame 21, but protrudes from the one surface. In the example illustrated in FIGS. 7 to 10, the AC adapter bracket 324 protrudes to the negative Z side with respect to the straight frame 21.

The AC adapter bracket 324 has such a shape because the information display device 1 is thin. Due to the limitation of the thickness, the AC adapter bracket 324 cannot be accommodated in the one surface of the straight frame 21. Thus, unlike the power button section, the waterproofness is not secured by simply applying the sealant agent to the side illustrated in FIG. 9 in a manner of one-stroke writing. It is desirable to apply the sealant agent also to the opposite side (negative Z side) to form another watertight portion (second watertight portion S2) as indicated by a one-dot chain line in FIG. 10.

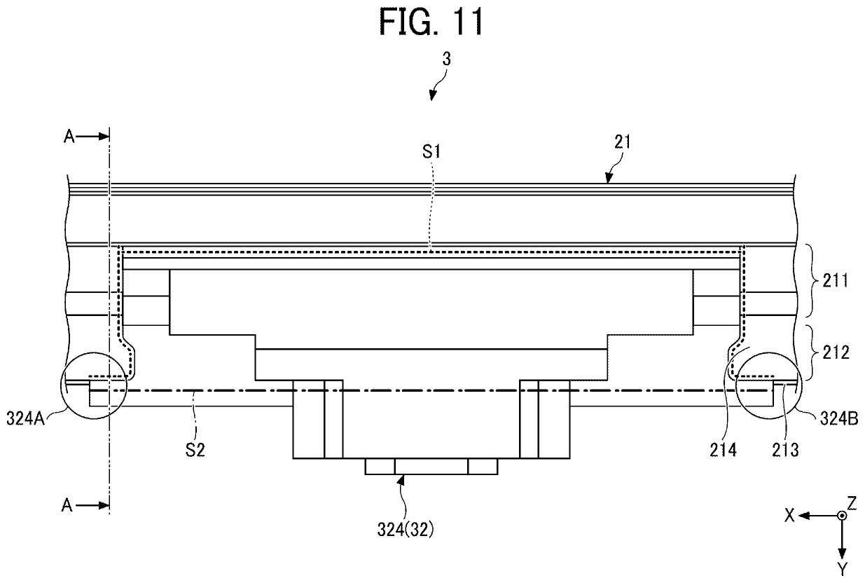

A description is given of the details of the application areas when the sealant agent is to be applied from both sides of the straight frame 21 (that is, the positive Z side and the negative Z side) like the AC adapter section, referring to FIG. 11.

FIG. 11 is a plan view of an example fastened state of the AC adapter bracket 324 and the straight frame 21 when viewed from the positive Z side (first direction). In FIG. 11, an area indicated by dotted lines is the above-described first watertight portion S1 to which the sealant agent is applied from the positive Z side (from the first direction, which is the near side on the plane on which FIG. 11 is drawn). In FIG. 11, an area indicated by a one-dot chain line is the above-described second watertight portion S2 to which the sealant agent is applied from the negative Z side (from a second direction opposite the first direction). The negative Z side is the deep side on the plane on which FIG. 11 is drawn.

As indicated by two circles of the ear portions 324A and 324B in FIG. 11, both end portions of the area (second watertight portion S2) to which the sealant agent is applied from the negative Z side (from the second direction, the deep side on the plane on which FIG. 11 is drawn) overlap both end portions of the area (first watertight portion S1) to which the sealant agent is applied from the positive Z side (from the first direction, the near side on the plane on which FIG. 11 is drawn), which is a characteristic feature of the present embodiment.

Even in the case where “the sealant agent is applied to extend to both sides of the straight frame 21 in the Z-direction” illustrated in FIGS. 9 and 10, the sealant agent can be applied in a manner of one-stroke writing like the case of the power button bracket 322 illustrated in FIG. 6. However, in this case, there is a disadvantage that it is difficult to stop water at an edge portion (an end face 213 described later) of the straight frame 21. This is because it is difficult to leave the sealant agent at the edge portion even when the sealant agent is left in any posture during drying, and because the sealant agent flows down due to the influence of gravity and it is difficult to ensure waterproof quality in mass production. Thus, in the present embodiment, the sealant agent is not applied in a manner of one-stroke writing, but an application area of the sealant agent is divided into two portions on the near side on the plane on which FIG. 11 is drawn (first watertight portion S1) and on the deep side on the plane on which FIG. 11 is drawn (second watertight portion S2) in FIG. 11, and the sealant agent is applied in each of the divided portions. There are a drying period after the application on the near side on the plane of the figure and a drying period after the application on the deep side of the drawing surface.

The present embodiment provides the structure in which, when the two watertight portions S1 and S2 are formed, both end portions of the first watertight portion S1 in the application area on the near side on the plane of the figure and both end portions of the second watertight portion S2 in the application area on the deep side on the plane of the figure (portions surrounded by two circles of the ear portions 324A and 324B in FIG. 11) overlap each other. Thus, even when the sealant agent is separately applied from both sides of the straight frame 21, adhesion between the AC adapter bracket 324 and the straight frame 21 can be ensured at both end portions (edge portions of the straight frame 21), and a waterproof structure with stable quality can be provided.

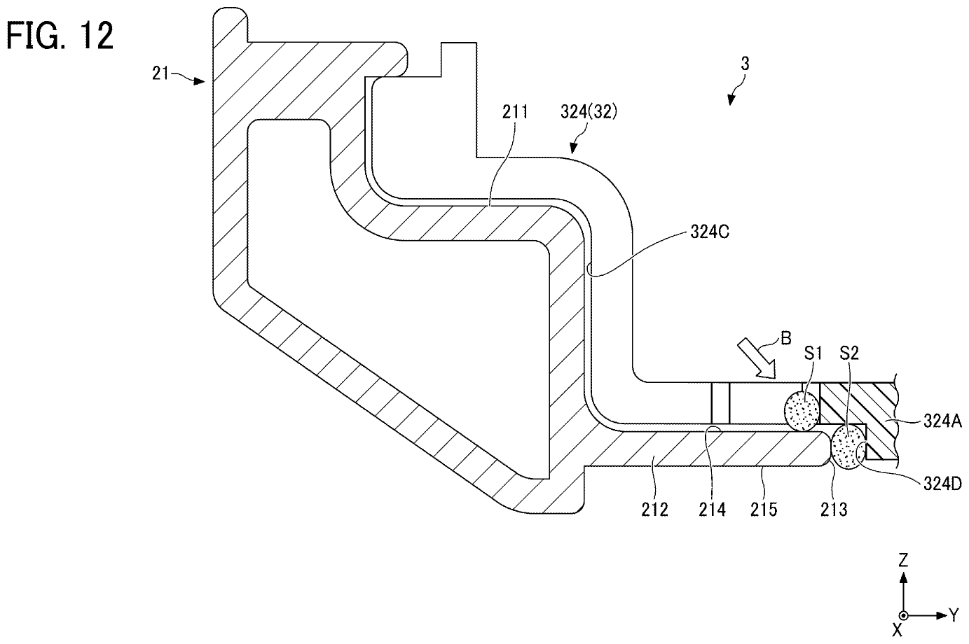

The joint structure of the AC adapter section of the interface frames 32 according to the embodiment is further described referring to FIG. 12 in addition to FIGS. 7 to 11. FIG. 12 is a cross-sectional view taken along line A-A in FIG. 11. The cross-sectional view in FIG. 12 is a cross-sectional view of a portion surrounded by the circle (ear portion 324A) in FIG. 11 when viewed from the positive X side.

The straight frame 21 (first part) has a longitudinal direction along one side of the enclosure shape of the frame structure 3 (in the example in FIGS. 8 to 12, the X-direction). As illustrated in FIGS. 8, 9, 11, and 12, the straight frame 21 has an inner side face 211 facing the center of the enclosure shape (in this example, the positive Y side), and a protruding portion 212 protruding from the inner side face 211 toward the center and extending along one side of the enclosure shape (X-direction).

In this example, the protruding portion 212 is a plate member having a relatively small dimension in the Z-direction as illustrated in FIG. 12. The protruding portion 212 has an end face 213 located at a distal end on the center side of the enclosure shape, a side face 214 (one side face) facing the front side (positive Z side, also referred to as a first direction), and a side face 215 (another side face) facing the rear side (negative Z side, also referred to as the second direction).

The side face 214 faces (or is adjacent to) the inner side face 211 on the positive Z side, and defines a face in the same direction integrally with the inner side face 211. “One face (a series of faces facing the inner side) of the straight frame 21” described above corresponds to a face including the inner side face 211 and the side face 214. “A face opposite to one face of the straight frame 21” corresponds to the side face 215.

The AC adapter bracket 324 (second part) is attached to an intermediate portion in the longitudinal direction of the straight frame 21. The AC adapter bracket 324 has a first face 324C facing the inner side face 211 of the straight frame 21 and the one side face 214 of the protruding portion 212, and a second face 324D facing the end face 213 of the protruding portion 212. That is, the shape of the AC adapter bracket 324 reaches the inner side face 211 of the straight frame 21, the side face 214 of the protruding portion 212 continuously connected to the inner side face 211, and the end face 213 at the distal end of the protruding portion 212.

The first watertight portion S1 is formed by applying a sealant agent (pressure sensitive adhesive) from the direction (orientation) of the one side face 214 (positive Z side) along an outer edge portion of the first face 324C of the AC adapter bracket 324 facing the inner side face 211 of the straight frame 21 and the one side face 214. The second watertight portion S2 is formed by applying the sealant agent from the direction (orientation) of the side face 215 of the protruding portion 212 (negative Z side) along a boundary portion with respect to the end face 213, of the second face 324D of the AC adapter bracket 324 facing the end face 213 of the straight frame 21.

In particular, according to the present embodiment, the AC adapter bracket 324 (second part) has portions surrounded by the two circles in FIG. 11. In the following description, the two portions are referred to as a pair of ear portions 324A and 324B.

The pair of ear portions 324A and 324B are formed to protrude on both sides in the longitudinal direction of the straight frame 21 from the AC adapter bracket 324 along the protruding portion 212. To the pair of ear portions 324A and 324B, the first face 324C and the second face 324D extend from the AC adapter bracket 324.

In the present embodiment, the first watertight portion S1 and the second watertight portion S2 are formed so that both ends of the first watertight portion S1 and the second watertight portion S2 extend to the positions of the pair of ear portions 324A and 324B and overlap each other at the pair of ear portions 324A and 324B. “Overlap” in the present embodiment represents that, at each of the ear portions 324A and 324B, the first watertight portion S1 and the second watertight portion S2 extend in parallel to each other in the same direction (in the example, the X-direction), extend to an edge end portion in the X-direction of the ear portion 324A or 324B, and overlap each other in a view in a certain direction (for example, a direction of arrow B illustrated in FIG. 12).

As described above, the frame structure 3 and the information display device 1 according to the present embodiment include the pair of ear portions 324A and 324B that are formed to protrude from the AC adapter bracket 324 (second part) along the protruding portion 212 and at which the first face 324C and the second face 324D extend, and the first watertight portion S1 and the second watertight portion S2 are formed so that the end portions of the first watertight portion S1 and the second watertight portion S2 extend to the positions of the ear portions 324A and 324B and overlap each other at the ear portions 324A and 324B.

With this configuration, even in the configuration illustrated in FIGS. 7 to 12 in which the shape of the straight frame 21 or the interface frame 32 is more complicated and a single watertight portion S having an enclosure shape, such as the typical waterproof structure illustrated in FIGS. 4 to 6, is not applicable, waterproofness is secured by the two watertight portions S1 and S2 provided from both sides in the Z-direction and overlapping each other at the ear portions 324A and 324B. Thus, in the present embodiment, in the example illustrated in FIGS. 7 to 12, waterproofness can be improved regardless of the shape or size of the frame structure 3 to be waterproofed.

In the present embodiment, one straight frame 21 (first part) of the pair of parts to be assembled is made of metal, and the other AC adapter bracket 324 (second part) is made of resin. When metal parts are assembled together or when resin parts are assembled together, waterproofness can be easily ensured by, for example, welding or melting. However, when a metal part and a resin part are assembled, these methods cannot be used, and hence it is difficult to ensure waterproofness by the method of related art. With the joining method of the present embodiment, waterproofness can be properly ensured even in the case of assembly of the metal part and the resin part as described above, and hence a particularly marked effect can be obtained in this case.

In the example illustrated in FIGS. 7 to 12, the protruding portion 212 of the straight frame 21 (first part) has the plate shape. However, the protruding portion 212 may have any structure as long as the protruding portion 212 protrudes at least toward the center of the enclosure shape of the frame structure 3, and may have, for example, a block shape having a relatively large dimension in the Z-direction. In this case, the second face 324D of the AC adapter bracket 324 (second part) may have any shape as long as the second watertight portion S2 can be formed at a boundary portion with respect to at least the end face, and may have a shape that covers the entire end face of the protruding portion in the Z-direction or a shape that covers a portion of the end face on the positive Z side. Alternatively, the second face 324D of the AC adapter bracket 324 (second part) may have a shape that covers the entire end face 213 of the protruding portion 212 and further covers at least a portion of the side face 215 on the negative Z side.

The waterproof structure of the frame structure according to the present embodiment can be manufactured, for example, in the following procedure. In a first stage, as illustrated in FIGS. 7 and 8, the AC adapter bracket 324 (second part) is attached to the straight frame 21 (first part) (attachment step). In the attachment step, for example, as described above, the AC adapter bracket 324 and the AC adapter cover 323 on the outer side sandwich the straight frame 21 and are secured to the straight frame 21 by screw fastening or the like.

In a second stage, after the attachment step, a sealant agent is applied from the direction of the one side face 214 along the outer edge portion of the first face 324C of the AC adapter bracket 324 facing the inner side face 211 of the straight frame 21 and the one side face 214 of the protruding portion 212 to form the first watertight portion S1 so that the end portions of the first watertight portion S1 extend to the positions of the ear portions 324A and 324B (first watertight portion formation step). At this time, for example, as illustrated in FIG. 9, the one side face 214 of the protruding portion 212 is desirably disposed to face upward. Thus, the sealant agent can be prevented from flowing before being solidified, and the first watertight portion S1 can accurately fill the gap between the straight frame 21 and the AC adapter bracket 324.

In a third stage, after the attachment step, the sealant agent is applied from the direction of the side face 215 (another side face) of the protruding portion 212 of the straight frame 21 along the boundary portion with respect to the end face 213, of the second face 324D of the AC adapter bracket 324 facing the end face 213 of the protruding portion 212 to form the second watertight portion S2 so that the end portions of the second watertight portion S2 extend to the positions of the ear portions 324A and 324B (second watertight portion formation step). At this time, for example, as illustrated in FIG. 10, in contrast to the second stage, the side face 215 of the protruding portion 212 is desirably disposed to face upward. Thus, the sealant agent can be prevented from flowing before being solidified, and the second watertight portion S2 can accurately fill the gap between the straight frame 21 and the AC adapter bracket 324.

The first watertight portion formation step in the second stage and the second watertight portion formation step in the third stage described above may be performed in the reverse order. In short, one step may be performed first to form one of the first watertight portion 51 and the second watertight portion S2, the one formed first may be solidified, and then the other step may be performed, thereby forming the first watertight portion 51 and the second watertight portion S2 to overlap each other at the ear portions 324A and 324B. Thus, both the first watertight portion S1 and the second watertight portion S2 can be easily formed to accurately fill the gap between the straight frame 21 and the AC adapter bracket 324.

Regarding the first watertight portion formation step in the second stage and the second watertight portion formation step in the third stage described above, it is desirable to perform the step of forming one of the first watertight portion S1 and the second watertight portion S2 using a larger amount of the sealant agent first. In the example illustrated in FIGS. 9 and 10, since the first watertight portion S1 is formed to be longer than the second watertight portion S2, a larger amount of sealant agent is used for the first watertight portion S1 than that for the second watertight portion S2, and hence the first watertight portion formation step is performed first. Thus, the first watertight portion S1 and the second watertight portion S2 can be more efficiently formed.

### Joint Structure of Corner Frame 31 According to Embodiment

Like the interface frame 32 such as the above-described AC adapter bracket 324, the corner frame 31 has a complicated shape and is not adoptable a single enclosed-shaped watertight portion S like the typical waterproof structure illustrated in FIGS. 4 to 6. Thus, also in the joint structure between the corner frame 31 and the straight frame 21, two watertight portions S1 and S2 are formed to ensure waterproofness, like the example in FIGS. 7 to 12.

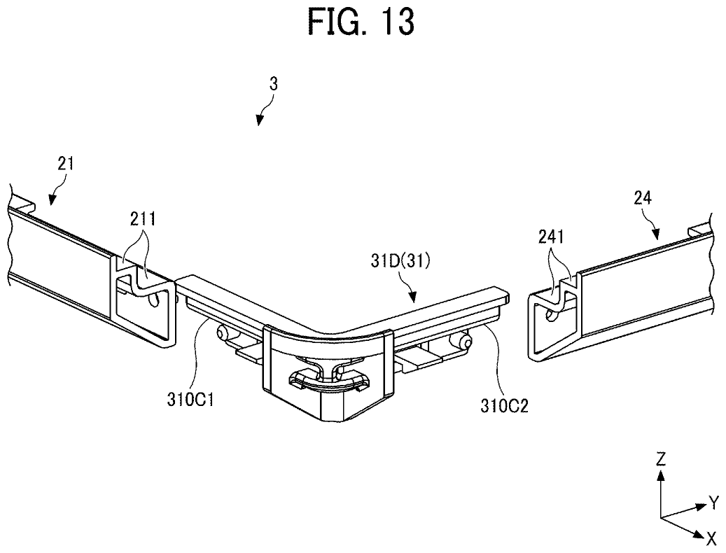

FIG. 13 is an exploded perspective view of an example corner section of the frame structure 3. FIG. 13 is a perspective view in the same direction as the direction of FIG. 3, and illustrates, in an enlarged view, a portion of the corner frame 31D disposed between the straight frame 24 and the straight frame 21 among the four corner frames 31A to 31D in FIG. 3. FIG. 13 is a view from the outer side of the frame structure 3. Since the joint structures of the other three corner frames 31A, 31B, and 31C are also similar to the joint structure of the frame 31D, the joint structures are collectively referred to as a “corner frame 31” in the following description for the convenience of description.

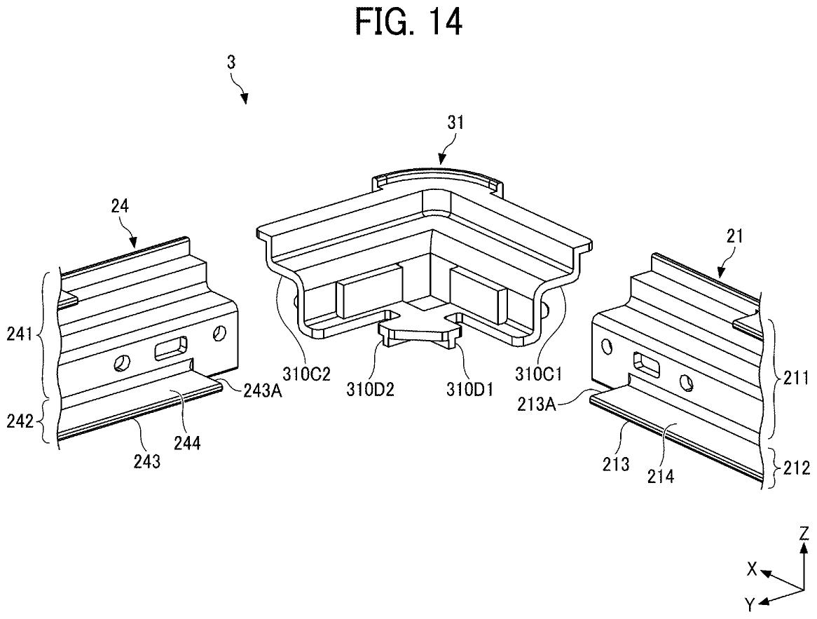

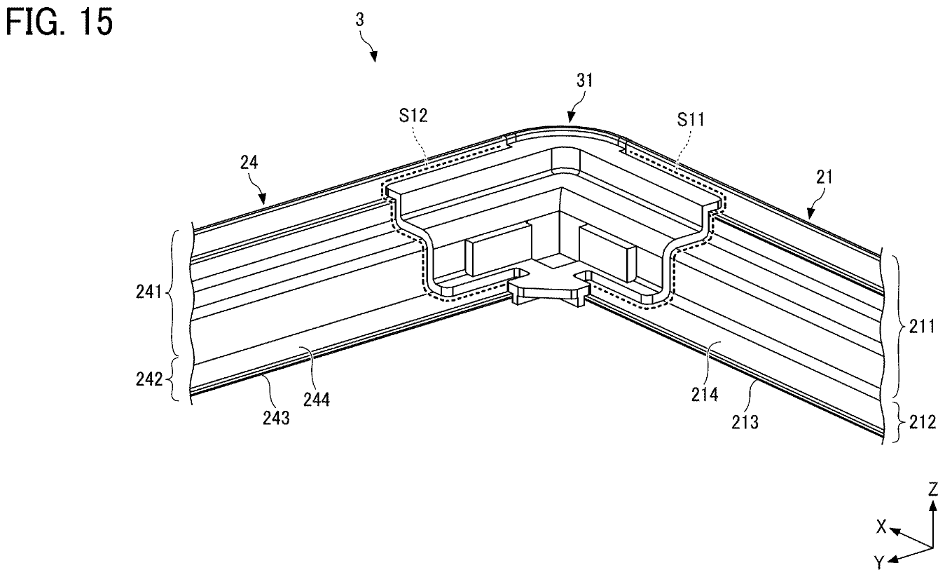

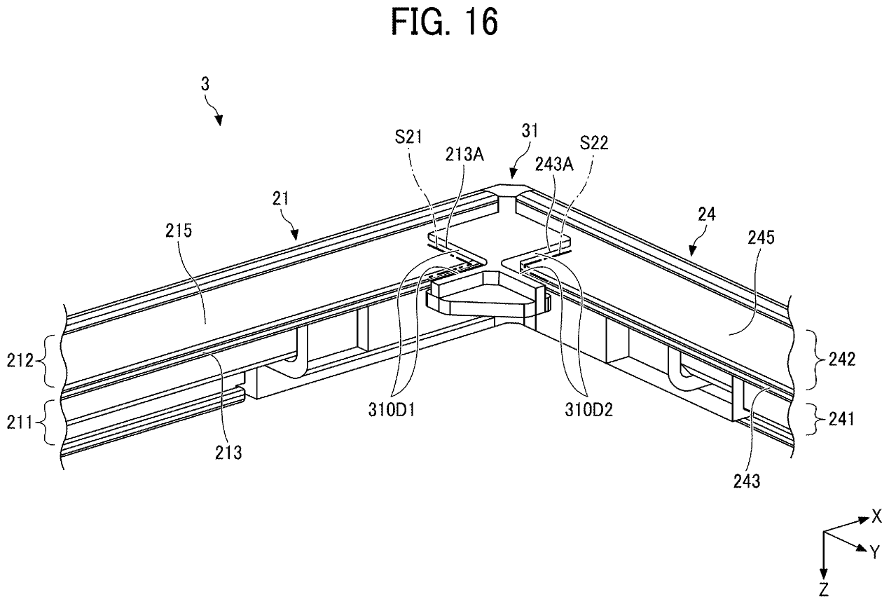

FIG. 14 is an exploded perspective view of the corner section illustrated in FIG. 13 when viewed from the inner side of the frame structure 3. FIG. 14 is a perspective view when the viewpoint is rotated by 180 degrees around the Z-axis with respect to FIG. 13. FIG. 15 is a perspective view illustrating a joined state of the corner section illustrated in FIG. 14. FIG. 15 is a perspective view from the same viewpoint as the viewpoint of FIG. 14, and is a perspective view in a state in which respective parts illustrated in FIG. 14 are assembled. FIG. 16 is a perspective view of the corner section in the joined state illustrated in FIG. 15 when viewed from the rear side. FIG. 16 is a perspective view when the viewpoint is rotated by 180 degrees around the Y-axis and rotated by 90 degrees around the Z-axis with respect to FIG. 15.

As illustrated in FIGS. 12 to 15, the corner section includes the corner frame 31 made of resin, and two of the straight frames 21 to 24 (in the drawings, the two straight frames 21 and 24 are illustrated) made of metal. The corner section has a structure that is secured by inserting the corner frame 31 into the two of the straight frames 21 to 24, unlike the power button section illustrated in FIGS. 4 to 6 and the AC adapter section illustrated in FIGS. 7 to 12. However, since waterproofing is not provided merely by insertion, waterproofing is provided by applying a sealant agent between the two of the straight frames 21 to 24 and the corner frame 31, like the power button section and the AC adapter section.

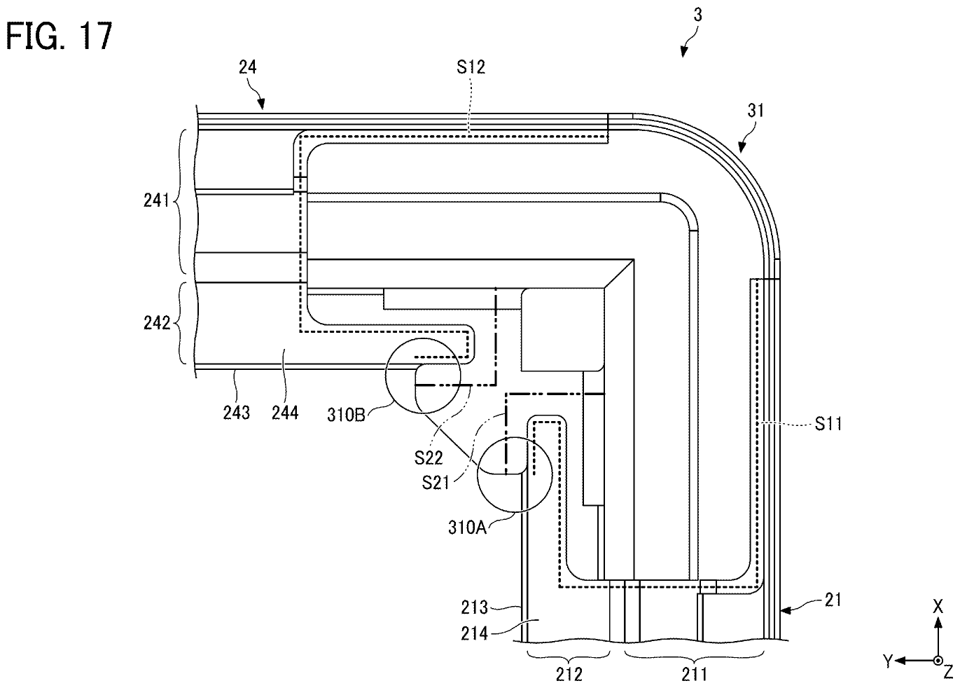

The relationship between the two of the straight frames 21 to 24 and the corner frame 31 is similar to that of the AC adapter section, and the corner frame 31 has a shape protruding from the two of the straight frames 21 to 24. In the example illustrated in FIGS. 13 to 16, the corner frame 31 protrudes to the negative Z side with respect to the two of the straight frames 21 to 24. Thus, as illustrated in FIGS. 15 and 16, the sealant agent is applied from both sides of the two of the straight frames 21 to 24 (that is, the positive Z side and the negative Z side) to form two sets of watertight portions, namely, first watertight portions S11 and S12 and second watertight portions S21 and S22. Details of the application areas will be described referring to FIG. 17.

FIG. 17 is a plan view of an example fastened state of the corner frame 31 and the straight frames 21 and 24 when viewed from the positive Z side. In FIG. 17, areas indicated by dotted lines are areas to which the sealant agent is applied from the near side on the plane on which FIG. 17 is drawn (positive Z side), and are the above-described first watertight portions S11 and S12. In FIG. 17, areas indicated by one-dot chain lines are areas to which the sealant agent is applied from the deep side on the plane on which FIG. 17 is drawn (negative Z side), and are the above-described second watertight portions S21 and S22.

Like the AC adapter section, as indicated by two circles (ear portions 310A and 310B) in FIG. 17, the present embodiment has a feature that end portions of the areas (second watertight portions S21 and S22) to which the sealant agent is applied from the deep side on the plane on which FIG. 17 is drawn overlap end portions of the areas (first watertight portions S11 and S12) to which the sealant agent is applied from the near side on the plane on which FIG. 17 is drawn. While both end portions overlap each other at the AC adapter section, one end portions overlap each other at the corner section.

The joint structure of the corner frame 31 according to the embodiment is further described.

As illustrated in FIGS. 13 to 17, the straight frame 24 (first part) has a longitudinal direction along one side of the enclosure shape of the frame structure 3 (in this example, the Y-direction). The straight frame 24 has an inner side face 241 facing the center of the enclosure shape (in this example, the negative X side), and a protruding portion 242 protruding from the inner side face 241 toward the center and extending along one side of the enclosure shape (Y-direction).

The structures of the inner side face 241 and the protruding portion 242 are similar to those of the inner side face 211 and the protruding portion 212 of the straight frame 21. The protruding portion 242 has an end face 243, one side face 244, and the other side face 245 similar to those of the protruding portion 212. The positions of end faces 243A on both sides in the extending direction of the protruding portion 242 are disposed closer than the positions of end portions of the inner side face 241 to an intermediate portion in the longitudinal direction of the straight frame 24 (in this example, the positive Y side).

The positions of end faces 213A on both sides in the extending direction of the protruding portion 212 of the straight frame 21 (first part) are disposed closer than the positions of end portions of the inner side face 211 to an intermediate portion in the longitudinal direction of the straight frame 21 (in this example, the negative X side). The other structures of the straight frame 21 (first part) are similar to those described referring to FIGS. 8 to 12, and hence the description is omitted.

The corner frame 31 (second part) is disposed between the two straight frames (in this example, the straight frames 21 and 24), is attached to end portions in the respective longitudinal directions of the straight frames 21 and 24, and couples the straight frames 21 and 24.

The corner frame 31 has a first face 310C1 facing the inner side face 211 of the straight frame 21 and the one side face 214 of the protruding portion 212, and a second face 310D1 facing the end faces 213 and 213A of the protruding portion 212. Likewise, the corner frame 31 has a first face 310C2 facing the inner side face 241 of the straight frame 24 and the one side face 244 of the protruding portion 242, and a second face 310D2 facing the end faces 243 and 243A of the protruding portion 242. That is, the shape of the corner frame 31 reaches, in addition to the inner side face 211 of the straight frame 21 and the side face 214 of the protruding portion 212 continuous with the inner side face 211, the end faces 213 and 213A at distal ends of the protruding portion 212. Likewise, the shape of the corner frame 31 reaches, in addition to the inner side face 241 of the straight frame 24 and the side face 244 of the protruding portion 242 continuous with the inner side face 241, the end faces 243 and 243A at distal ends of the protruding portion 242.

The first watertight portion S11 is formed by applying a sealant agent (pressure sensitive adhesive) from the direction of the one side face 214 (positive Z side) along an outer edge portion of the first face 310C1 of the corner frame 31 facing the inner side face 211 of the straight frame 21 and the one side face 214. The second watertight portion S21 is formed by applying the sealant agent from the direction of the other side face 215 of the protruding portion 212 (negative Z side) along a boundary portion with respect to the end faces 213 and 213A, of the second face 310D1 of the corner frame 31 facing the end face 213 of the straight frame 21.

Likewise, the first watertight portion S12 is formed by applying the sealant agent from the direction of the one side face 244 (positive Z side) along an outer edge portion of the first face 310C2 of the corner frame 31 facing the inner side face 241 of the straight frame 24 and the one side face 244. The second watertight portion S22 is formed by applying the sealant agent from the direction of the other side face 245 of the protruding portion 242 (negative Z side) along a boundary portion with respect to the end faces 243 and 243A, of the second face 310D2 of the corner frame 31 facing the end face 243 of the straight frame 24.

In particular, according to the present embodiment, the corner frame 31 (second part) has portions surrounded by the two circles (ear portions 310A and 310B) in FIG. 17. In the following description, the two portions are referred to as a pair of ear portions 310A and 310B.

The pair of ear portions 310A and 310B are formed to protrude from the coupling positions of the corner frame 31 and the two straight frames 21 and 24 toward the intermediate portions in the respective longitudinal directions of the straight frames 21 and 24. The pair of ear portions 310A and 310B have the first faces 310C1 and 310C2 and the second faces 310D1 and 310D2 extending from the corner frame 31.

In the present embodiment, the first watertight portions S11 and S12 and the second watertight portions S21 and S22 are formed so that one ends of the first watertight portions S11 and S12 and the second watertight portions S21 and S22 on the sides of the ear portions 310A and 310B extend to the positions of the pair of ear portions 310A and 310B and overlap each other at the pair of ear portions 310A and 310B. “Overlap” in this example represents that, in one ear portion 310A, the first watertight portion S11 and the second watertight portion S21 extend in parallel to each other in the same direction (in this example, the X-direction), extend to an edge end portion in the X-direction of the ear portion 310A, and overlap each other in a view in a certain direction (for example, the direction of arrow B illustrated in FIG. 12). Also, “overlap” in this example represents that, in the other ear portion 310B, the first watertight portion S12 and the second watertight portion S22 extend in parallel to each other in the same direction (in this example, the Y-direction), extend to an edge end portion in the Y-direction of the ear portion 310B, and overlap each other in a view in a certain direction (for example, the direction of arrow B illustrated in FIG. 12).

As described above, the frame structure 3 and the information display device 1 according to the present embodiment include the pair of ear portions 310A and 310B that are formed to protrude from the corner frame 31 (second part) along the protruding portions 212 and 242 and in which the first faces 310C1 and 310C2 and the second faces 310D1 and 310D2 extend, and the first watertight portions S11 and S12 and the second watertight portions S21 and S22 are formed so that end portions of the first watertight portions S11 and S12 and the second watertight portions S21 and S22 extend to the positions of the ear portions 310A and 310B and overlap each other at the ear portions 310A and 310B.

With this configuration, even in the configuration illustrated in FIGS. 13 to 17 in which the shapes of the two of the straight frames 21 to 24 and the corner frame 31 are more complicated and a single enclosure-shaped watertight portion S such as the typical waterproof structure illustrated in FIGS. 4 to 6 is not applicable, waterproofness is secured by the two sets of watertight portions, namely, the first watertight portions S11 and S12 and the second watertight portions S21 and S22 provided from both sides in the Z-direction and overlapping each other at the ear portions 310A and 310B. Thus, in the present embodiment, even in the example illustrated in FIGS. 13 to 17, waterproofness can be improved regardless of the shape or size of the frame structure 3 to be waterproofed.

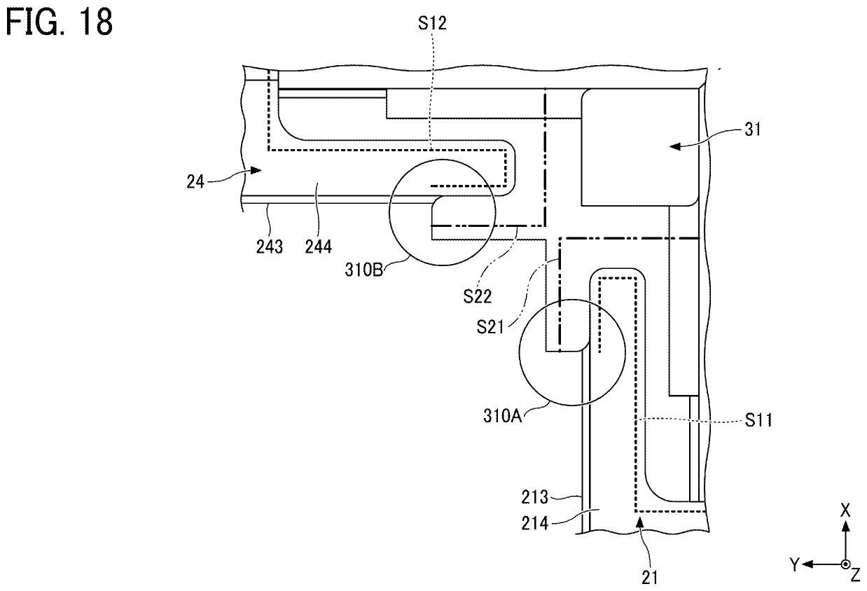

FIG. 18 is a schematic view illustrating a corner frame 31 according to a modification of the embodiment. Referring to FIGS. 13 to 17, the ear portions 310A and 310B of the corner frame 31 are formed as one part having a substantially triangular shape in plan view in the Z-direction for easier manufacturing. However, strictly speaking, each of the ear portions 310A and 310B includes two elements that exhibit a waterproof function with respect to the two of the straight frames 21 to 24 that are coupled to each other. That is, the ear portions 310A and 310B of the corner frame 31 may have other shapes as long as the corner frame 31 has the two elements. For example, as illustrated in FIG. 18, the pair of ear portions 310A and 310B may extend in the longitudinal directions (X-direction and Y-direction) of the straight frames 21 and 24 and may be formed in a substantially L-shape in which the respective longitudinal directions are substantially orthogonal to each other.

While the corner frame 31 exemplified referring to FIGS. 13 to 17 couples the two of the straight frames 21 to 24 in substantially right angle directions, the coupling structure by the corner frame 31 is not limited to this example. For example, when a waterproof joint structure similar to that of the corner frame 31 is applied to a resin frame that couples two of the straight frames 21 to 24 in the same direction, a waterproof effect similar to that of the corner frame 31 can be attained.

The present embodiments are described with reference to specific examples. However, the present disclosure is not limited to these embodiments. Those in which a person skilled in the art makes appropriate design changes to these specific examples are also included in the scope of the present disclosure as long as they have the features of the present disclosure. The elements, arrangement, condition, shape, and the like of each of the above-described specific examples are not limited to those illustrated, and may be changed as appropriate. As long as there is no technical contradiction, the combination of elements provided in each of the above-described specific examples can be appropriately changed.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

In one aspect, a frame structure includes a plurality of parts that are assembled in an enclosure shape, the plurality of parts including a first part, a second part, a first watertight portion, a second watertight portion, and an ear portion. The first part is formed to have a longitudinal direction along the enclosure shape of the frame structure, and the first part includes an inner side face facing a center of the enclosure shape and a protruding portion protruding from the inner side face toward the center and extending in the direction of the enclosure shape. The second part is assembled with the first part, and the second part includes a first face facing the inner side face of the first part and one side face of the protruding portion facing a side of the inner side face, and a second face facing an end face of the protruding portion. The first watertight portion is formed of a pressure sensitive adhesive applied from a direction of the one side face along an outer edge portion of the first face of the second part facing the inner side face of the first part and the one side face. The second watertight portion is formed of the pressure sensitive adhesive applied from a direction of another side face of the protruding portion opposite to the one side face along a boundary portion with respect to the end face, of the second face of the second part facing the end face of the first part. The ear portion is formed to protrude from the second part along the protruding portion, the first face and the second face extending to provide the ear portion. The first watertight portion and the second watertight portion are formed so that end portions of the first watertight portion and the second watertight portion extend into the ear portion and overlap each other in the ear portion.

Another aspect concerns a method of manufacturing a frame structure including a plurality of parts that are assembled in an enclosure shape. The plurality of parts includes a first part, a second part, and an ear portion. The first part is formed to have a longitudinal direction along the enclosure shape of the frame structure, and the first part includes an inner side face facing a center of the enclosure shape and a protruding portion protruding from the inner side face toward the center and extending in the direction of the enclosure shape. The second part is assembled with the first part, and includes a first face facing the inner side face of the first part and one side face of the protruding portion facing a side of the inner side face, and a second face facing an end face of the protruding portion. The ear portion is formed to protrude from the second part along the protruding portion, the first face and the second face extending to provide the ear portion

The method includes attaching the second part to the first part; after the attaching, applying a pressure sensitive adhesive from a direction of the one side face along an outer edge portion of the first face of the second part facing the inner side face of the first part and the one side face to form a first watertight portion so that an end portion of the first watertight portion extends to a position of the ear portion; and, after the attaching, applying the pressure sensitive adhesive from a direction of another side face of the protruding portion opposite to the one side face along a boundary portion with respect to the end face, of the second face of the second part facing the end face of the first part to form a second watertight portion so that an end portion of the second watertight portion extends to the position of the ear portion.

One of the forming the first watertight portion and the forming the second watertight portion is performed first to form one of the first watertight portion and the second watertight portion first, the one formed first is solidified, and then another one of the forming the first watertight portion and the forming the second watertight portion is performed to form the first watertight portion and the second watertight portion to overlap each other at the ear portion.

1. A frame structure comprising
a plurality of parts assembled to have an enclosure shape, the plurality of parts including:
a first part having a longitudinal direction along a side of the enclosure shape of the frame structure, the first part including:
an inner side face facing a center of the enclosure shape; and
a protruding portion protruding from the inner side face toward the center of the enclosure shape and extending along the side of the enclosure shape, the protruding portion including a side face adjacent to the inner side face;
a second part attached to the first part and including:
a first face facing the inner side face of the first part and the side face of the protruding portion; and
a second face facing an end face of the protruding portion;
an ear portion protruding along the protruding portion from the second part, the ear portion into which the first face and the second face of the second part extend;
a first watertight portion including a pressure sensitive adhesive, the pressure sensitive adhesive being applied along an outer edge of the first face of the second part on the inner side face and the side face of the protruding portion; and
a second watertight portion including the pressure sensitive adhesive, the pressure sensitive adhesive being applied along a boundary with the end face of the protruding portion on the second face of the second part,
the first watertight portion and the second watertight portion overlapping each other in the ear portion.

2. The frame structure according to claim 1,
wherein the second part is attached to an intermediate portion in the longitudinal direction of the first part,
wherein the ear portion includes a pair of ear portions protruding to both sides in the longitudinal direction along the protruding portion, and
wherein the first watertight portion and the second watertight portion extend into the pair of ear portions and overlap each other in the pair of ear portions.

3. The frame structure according to claim 1,
wherein the first part includes two first parts, the second part is disposed between the two first parts and attached to end portions in respective longitudinal directions of the two first parts to couple the two first parts,
wherein the ear portion includes a pair of ear portions protruding from coupling positions of the second part and the two first parts toward intermediate portions in the respective longitudinal directions of the two first parts, and
wherein the first watertight portion and the second watertight portion extend into the pair of ear portions and overlap each other in the pair of ear portions.

4. The frame structure according to claim 1,
wherein the first part includes metal, and the second part includes resin.

5. An information display device comprising:
the frame structure according to claim 1; and
a front face portion attached to one side in a center axis direction of the enclosure shape of the frame structure, the front face portion including a screen on which information is displayed.

6. A method for manufacturing a frame structure including a plurality of parts assembled to have an enclosure shape, the plurality of parts including:
a first part having a longitudinal direction along a side of the enclosure shape of the frame structure, the first part including an inner side face facing a center of the enclosure shape, and a protruding portion protruding from the inner side face toward the center of the enclosure shape and extending along the side of the enclosure shape, the protruding portion including one side face adjacent to the inner side face;
a second part attached to the first part and including a first face facing the inner side face of the first part and the one side face of the protruding portion, and a second face facing an end face of the protruding portion;
an ear portion protruding along the protruding portion from the second part,
the method comprising:
attaching the second part to the first part;
after the attaching, applying a pressure sensitive adhesive, along an outer edge of the first face of the second part, from a direction of the one side face, to form a first watertight portion extending into the ear portion; and
after the attaching, applying the pressure sensitive adhesive, along a boundary with the end face of the protruding portion on the second face of the second part, from a direction of another side face of the protruding portion opposite to the one side face, to form a second watertight portion extending into the ear portion,
wherein one of the first watertight portion and the second watertight portion is formed and solidified prior to forming the other of the first watertight portion and the second watertight portion, and
wherein the first watertight portion and the second watertight portion are formed to overlap each other in the ear portion.

7. The method according to claim 6,
wherein one of the first watertight portion and the second watertight portion formed using a larger amount of the pressure sensitive adhesive is formed prior to forming the other of the first watertight portion and the second watertight portion.
